(19) United States
(12) Patent Application Publication
(10) Pub. No.: US 2013/0128673 A1
(43) Pub. Date: May 23, 2013

(54) SEMICONDUCTOR MEMORY DEVICE

(71) Applicants: Yuri TERADA, Yokohama-shi (JP); Dai Nakamura, Fujisawa-shi (JP); Takeshi Hioka, Yokohama-shi (JP)

(72) Inventors: Yuri TERADA, Yokohama-shi (JP); Dai Nakamura, Fujisawa-shi (JP); Takeshi Hioka, Yokohama-shi (JP)

(21) Appl. No.: 13/424,519

(22) Filed: Mar. 20, 2012

(30) Foreign Application Priority Data
Nov. 21, 2011 (JP) 2011-254127

(51) Int. Cl. G11C 16/06

(52) U.S. Cl. 365/185.23

(57) ABSTRACT

According to one embodiment, a semiconductor memory device includes memory cells storing data based on respective threshold voltages, having a positive threshold voltage in a data erased state, and includes respective control electrodes. Word lines are selectively electrically connected to the control electrodes of the memory cells, and charged to a potential before writing data to the memory cells. A voltage generator outputs a voltage at an output and includes a first path which discharges the output. A connection circuit is selectively electrically connected to the output of the voltage generator and a first word line, and selectively electrically connects the first word line to a first node which supplies a potential.

### CROSS-REFERENCE TO RELATED APPLICATIONS

This application is based upon and claims the benefit of priority from prior Japanese Patent Application No. 2011-254127, filed Nov. 21, 2011, the entire contents of which are incorporated herein by reference.

### FIELD

Embodiments described herein relate generally to a semiconductor memory device.

### BACKGROUND

A NAND flash memory is known. The NAND flash memory has NAND strings each of which includes serially-connected memory cell transistors. A small size NAND flash memory suffers from an influence by coupling between adjacent word lines. The coupling increases time taken for charging and discharging word lines, which prohibits a high-speed operation by the NAND flash memory.

### BRIEF DESCRIPTION OF THE DRAWINGS

FIG. 1 illustrates a sectional view of a NAND string of a plane NAND flash memory.

FIG. 2 illustrates a timing chart of voltages during data programming by the memory of FIG. 1.

FIG. 3 illustrates a block diagram of a semiconductor memory device according to a first embodiment.

FIG. 4 illustrates a perspective diagram of a part of a memory cell array.

FIG. 5 illustrates a circuit diagram of a part of the memory cell array.

FIG. 6 illustrates a sectional view of a part of the memory cell array.

FIG. 7 illustrates distribution of threshold voltages of memory cell transistors.

FIG. 8 illustrates a circuit diagram of a voltage generator according to the first embodiment.

FIG. 9 illustrates a timing chart of voltages in the voltage generator and associated components according to the first embodiment.

FIG. 10 illustrates a circuit diagram of a voltage generator according to a second embodiment.

FIG. 11 illustrates a timing chart of voltages in the voltage generator and associated components according to the second embodiment.

FIG. 12 illustrates another timing chart of voltages in the voltage generator and associated components according to the second embodiment.

FIG. 13 illustrates a still another timing chart of voltages in the voltage generator and associated components according to the second embodiment.

FIG. 14 illustrates a circuit diagram of a voltage generator and a part of a word line controller according to a third embodiment.

FIG. 15 illustrates a timing chart of voltages in the voltage generator and associated components according to the third embodiment.

FIG. 16 illustrates a circuit diagram of a voltage generator and a part of a word line controller according to a fourth embodiment.

### DETAILED DESCRIPTION

In general, according to one embodiment, a semiconductor memory device includes memory cells storing data based on respective threshold voltages, having a positive threshold voltage in a data erased state, and comprising respective control electrodes. Word lines are selectively electrically connected to the control electrodes of the memory cells, and charged to a potential before writing data to the memory cells. A voltage generator outputs a voltage at an output and includes a first path which discharges the output. A connection circuit is selectively electrically connected to the output of the voltage generator and a first word line, and selectively electrically connects the first word line to a first node which supplies a potential.

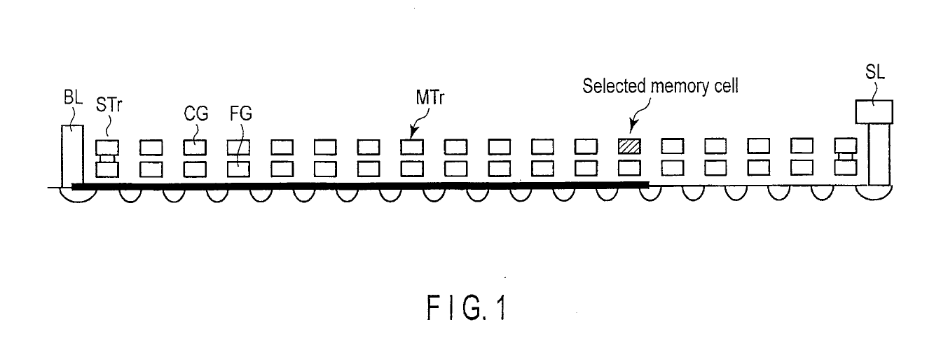

The inventors have obtained the following knowledge in the process of development of embodiments. The NAND flash memory has NAND strings each of which includes serially-connected memory cell transistors. Writing (programming) data to a selected memory cell requires each channel of specific memory cell transistors to have a specific voltage before applying voltages to the word lines (or, control gate electrodes CG). Referring to FIG. 1, the channels of all memory cell transistors MTr in bit-line side from the selected memory cell need to have voltage VSS, foe example. In order to transfer such a voltage, voltage VSS is applied to the memory cell transistor MTr at the end of the NAND string via a turned-on select gate transistor STr from the bit line BL, and this voltage needs to be relayed to the next transistors one by one. To this end, the memory cell transistors MTr need to be on. In the NAND flash memory, the erased memory cell transistors generally have a negative threshold voltage, and therefore they are always on. Voltages can be transferred through memory cell transistors with no additional operation for turning them on as illustrated with a thick line. Note that reference number FG indicates a floating gate.

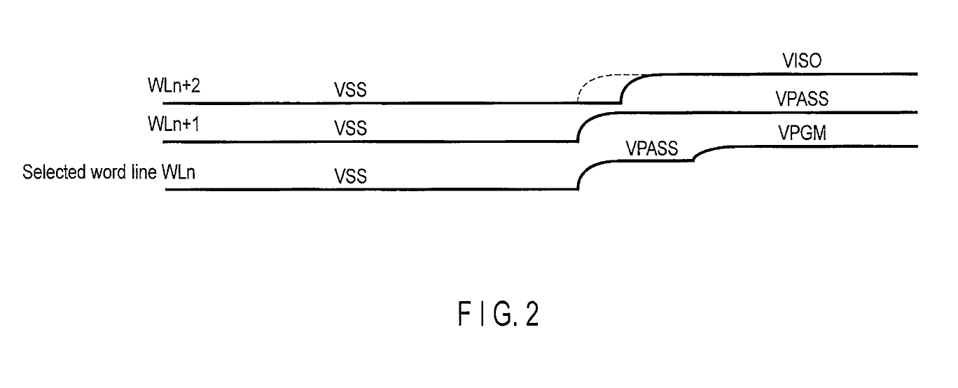

After such control of the channel voltages of memory cell transistors, particular word lines are charged to various voltages determined based on the selected memory cell transistor. Specifically, a word line of the selected memory cell (or, selected word line) receives a program voltage VPGM, and a word line adjacent the selected word line receives a voltage VPASS. A word line adjacent the word line which receives voltage VPASS receives a boost isolation voltage VISO. Since the difference between voltages VISO and VPASS is large, the word line which receives voltage VISO may be strongly influenced by coupling from the word line which receives voltage VPASS. Referring to FIG. 2, a countermeasure is examined that start of charging word line WLn+2, which receives voltage VISO, is made to occur after start of charging the neighboring word lines WLn and WLn+1 instead of the same timing (indicated by the dashed line) and word line WLn+2 is fixed to voltage VSS during the rise of voltage VPASS (indicated by the solid line).

There is a so-called three-dimensional-structure NAND flash memory, which is manufactured using a process with BiCS techniques as one of the types of NAND flash memory and may be referred to as a BiCS memory or a BiCS-type flash memory hereinafter. An erased memory cell transistor needs to have a positive threshold voltage in the BiCS memory and is normally off unlike in the NAND flash memory of the conventional two-dimensional structure, which may be referred to as a plane memory. The reason is that an insulating charge storage layer is shared by more than one memory cell transistors in the BiCS memory and therefore it may deteriorate data retention when a memory cell transistor with a negative threshold voltage is adjacent another memory cell transistor with a positive threshold voltage as will be described in detail later. With such a phenomenon, in order to control the channel voltages of the memory cell transistors in the NAND string, one or more memory cell transistors whose channel voltages need to be controlled need to receive a channel precharge voltage VCHPCH to be turned on. The voltage VCHPCH is generated by the same voltage generator as the voltage VISO, and the output of such a voltage generator is switched from the voltage VCHPCH to the voltage VISO at the same timing of charging the voltages VPGM and VPASS. For this reason, it is difficult to adopt this techniques of the BiCS memory to fix to the voltage VSS the word line which will be charged to the voltage VISO, immediately after the start of charging the voltage VPASS as is used in the plane memory in order to reduce the coupling. Therefore, the word line which will be charged to the voltage VISO severely suffers from the coupling in the BiCS memory. Furthermore, since the BiCS memory has a larger load capacity on their word lines than the plane memory, it suffers from larger influence of the coupling. These phenomena inhibit high-speed operation by the memory.

Embodiments configured based on such findings will now be described with reference to drawings. Components which have substantially the same functions and configurations will be referred to with the same reference numbers and repetitive descriptions will be given only when required. Embodiments described in the following illustrate devices and methods for realizing the technical idea of the embodiments, and the technical idea of the embodiments does not limit details to ones introduced below. The technical idea of the embodiments may be variously changed in accordance with the scope of the claims.

### First Embodiment

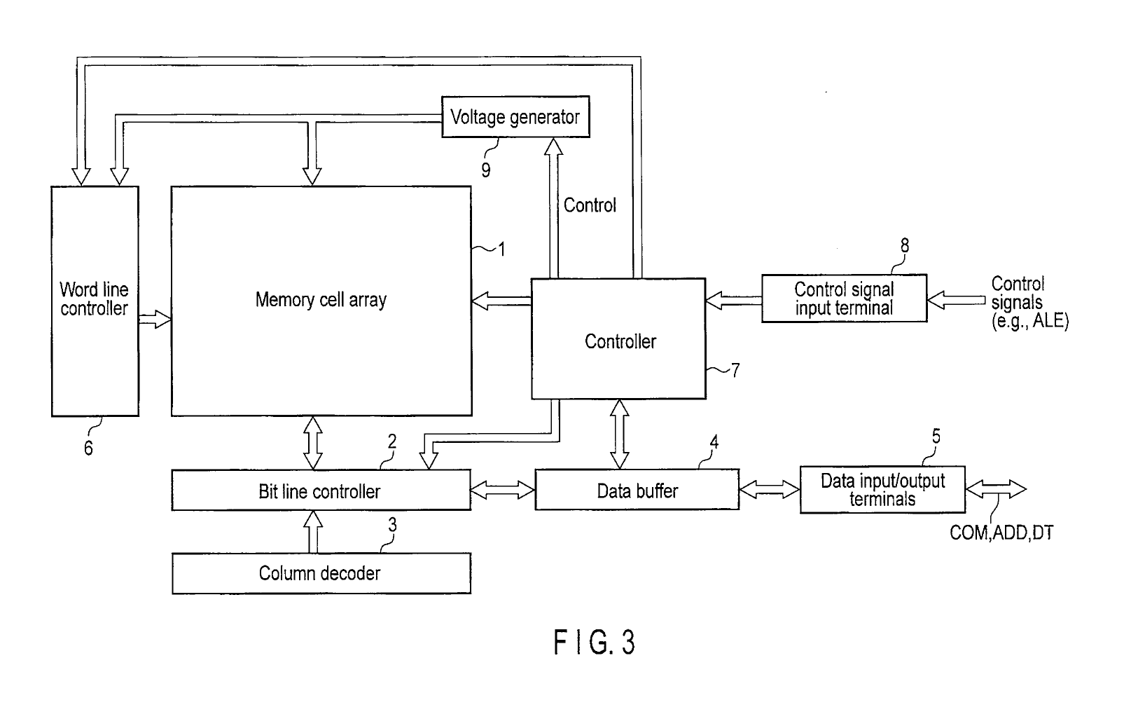

FIG. 3 illustrates a block diagram of a configuration of the whole semiconductor memory device according to the first embodiment. As shown in FIG. 3, a semiconductor memory device (NAND flash memory) includes a memory cell array 1, a bit line controller 2, a column decoder 3, a data buffer 4, a set of data input/output terminals 5, a word line controller 6, a controller 7, a set of control signal input terminal 8, and a voltage generator 9. It is not necessary that these functional blocks are distinguished as illustrated. Particularly, a part of a function may be performed by a functional block different from a functional block described in the following description. Furthermore, an illustrated functional block may be divided into smaller functional subblocks. Thus, the embodiments are not limited by illustrated functional blocks.

The memory cell array 1 includes blocks, each of which includes components such as memory cells, word lines, and bit lines. One block includes pages, which includes more than one memory cells and will be described in detail later. The memory cell array 1 is electrically connected to the bit line controller 2, word line controller 6, controller 7, and voltage generator 9.

The bit line controller 2 reads data stored in the memory cells in the memory cell array 1 via the bit lines, and detects the state of memory cells via the bit lines. The bit line controller 2 applies a write (or, program) voltage to the memory cells via the bit lines to write data in these memory cells in the memory cell array 1. The column decoder 3, data buffer 4, and controller 7 are electrically connected to the bit line controller 2.

The bit line controller 2 includes components such as sense amplifiers (S/As), data storage circuits (not shown). A specific data storage circuit is selected by the column decoder 3. Data stored in the memory cells is read to the selected data storage circuit and output outside from the data input/output terminals 5 via the data buffer 4. The data input/output terminals 5 are connected to a device outside the NAND flash memory such as a host device or a memory controller. The data input/output terminals 5 receive various commands COM and addresses ADD for controlling operation of the NAND flash memory, and receive and output data DT. Write data DT received at the data input/output terminals 5 is supplied to a specific data storage circuit selected by the column decoder 3 via the data buffer 4. The commands COM and addresses ADD are supplied to the controller 7. The sense amplifiers amplify potentials on the bit lines.

The word line controller 6 selects a specific word line in the memory cell array 1 based on control by the controller 7. The word line controller 6 receives voltages for reading, writing, or erasing data from the voltage generator 9. The word line controller 6 applies the received voltages to selected word lines.

The controller 7 is electrically connected to the memory cell array 1, bit line controller 2, column decoder 3, data buffer 4, word line controller 6, and voltage generator 9, and controls them. The controller 7 is connected to the control signal input terminals 8, and is controlled by control signals such as an address latch enable (ALE) signal received via the control signal input terminals 8 from the outside. The controller 7 also outputs control signals to the voltage generator 9, and controls it.

The voltage generator 9 provides necessary voltages during writing, reading, or erasing data to the memory cell array 1 and word line controller 6 based on control by the controller 7. Specifically, the voltage generator 9 generates at least a program voltage VPGM, a voltage VPASS, and an isolation voltage VISO during data writing.

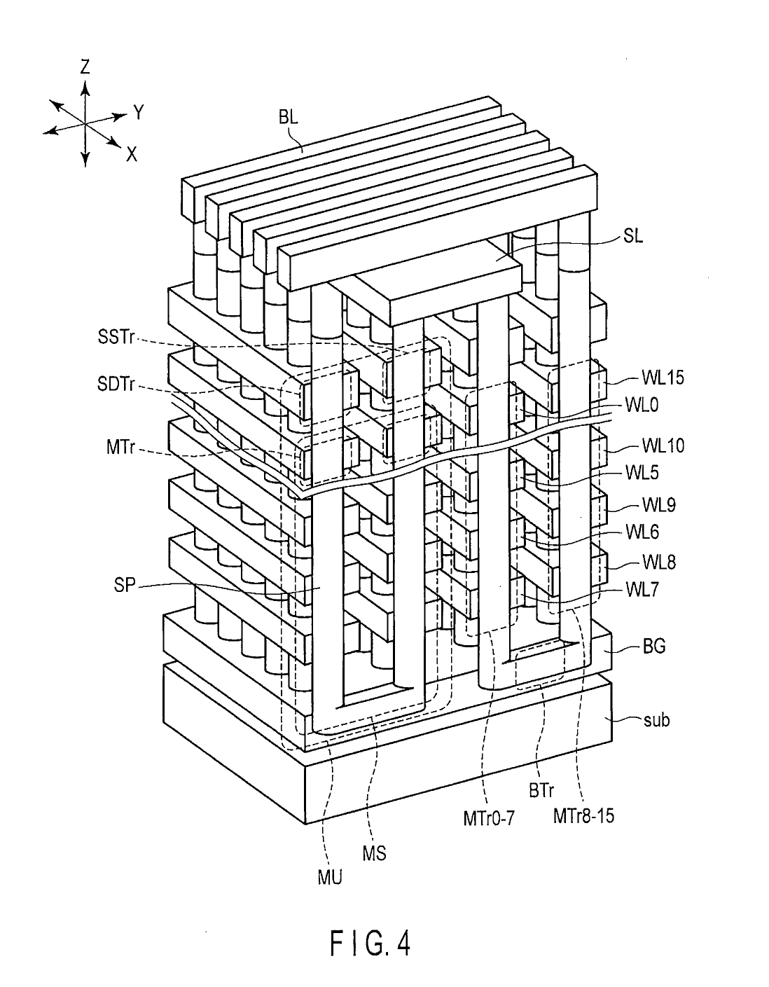

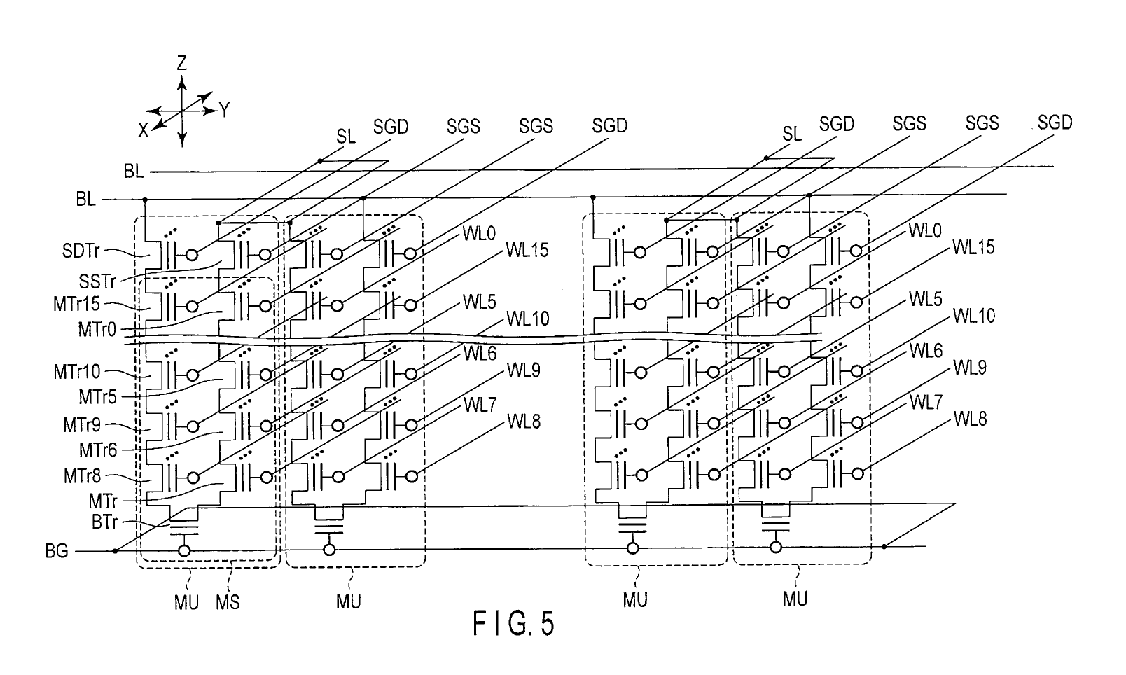

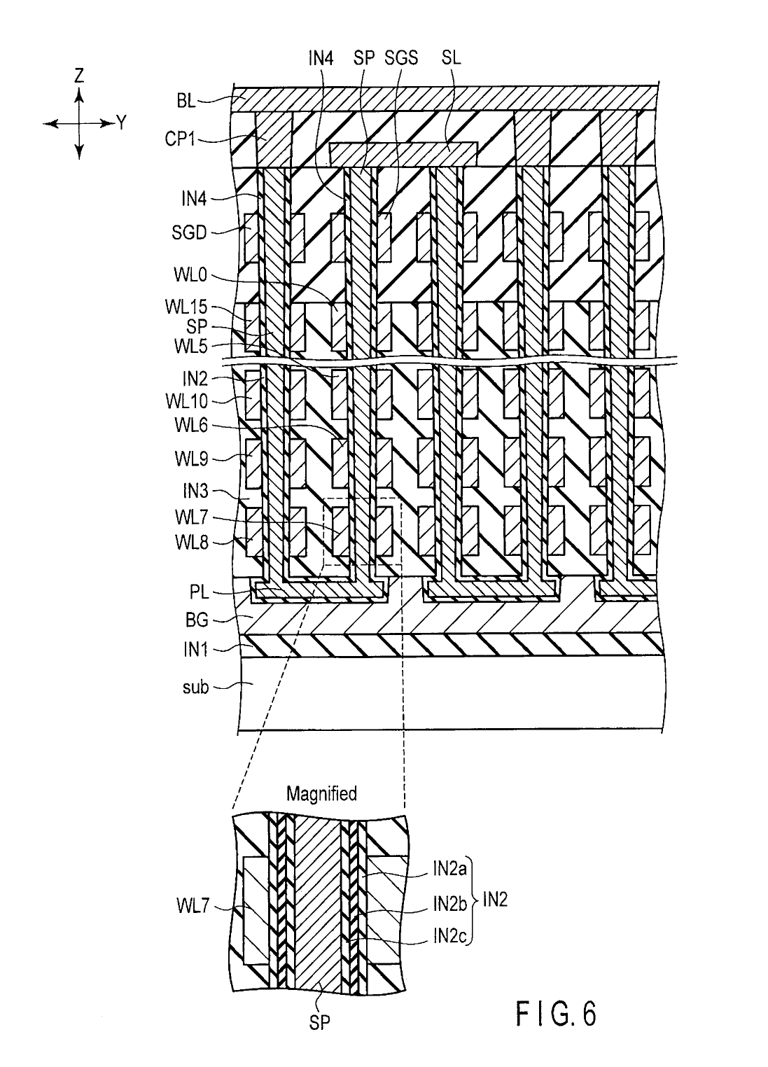

The memory cell array 1 has a three-dimensional structure illustrated in FIGS. 4 to 6. FIG. 4 illustrates a perspective view of a part of the memory cell array 1. FIG. 5 illustrates a circuit diagram of a part of the memory cell array 1. FIG. 6 illustrates a sectional view along the yz plane of a part of the memory cell array 1. Some features shown in one of FIGS. 4 to 6 may be omitted in another one for purpose of clarification of the figures. As shown in FIGS. 4 to 6, a back gate BG, which includes or consists of a conductive material, is formed above a substrate sub along the z-axis with an insulating layer IN1 interposed therebetween. The back gate BG extends along the xy plane. Memory units MU are also formed above the substrate sub along the z-axis. The memory units MU are in line along the x-axis and y-axis to form a matrix.

Each memory unit MU includes a select gate transistor SDTr, a memory string MS, and a select gate transistor SSTr. The memory string MS includes serially-connected memory cell transistors (e.g., sixteen transistors) MTr0 to MTr15. The memory cell transistors MTr0 to MTr7 are in line along the z-axis toward the substrate sub in the mentioned order. The memory cell transistors MTr8 to MTr15 are in line along the z-axis from the substrate sub in the mentioned order. The set of the memory cell transistors MTr0 to MTr7 and the set of the memory cell transistors MTr8 to MTr15 are connected via a back gate transistor BTr.

The select gate transistors SSTr and SDTr are above the memory cell transistors MTr0 and MTr15 along the z-axis, respectively. The select gate transistors SSTr and SDTr are connected to the memory cell transistors MTr0 and MTr15, respectively. Above the select gate transistors SSTr and SDTr along the z-axis, a source line SL and a bit line BL extend along the x-axis and y-axis, respectively. The select gate transistors SSTr and SDTr are connected to the source line SL and bit line BL, respectively.

The memory cell transistors MTr0 to MTr15 include a common semiconductor pillar SP, and a common insulating layer IN2 on the surface of the semiconductor pillar SP, and they include word lines (or, control gates) WL0 to WL15 extending along the x-axis, respectively. The semiconductor-pillars SP extend along the z-axis, are in line along the x-axis and y-axis to form a matrix, and include semiconductor such as silicon, which is buried in a hole in an interlayer insulation film IN3 above the back gate BG and has impurities introduced. Source/drain areas are formed in the semiconductor pillars SP. Source/drain areas of adjacent memory cell transistors MTr are connected. Two semiconductor pillars SP for who configure one memory string MS are electrically connected via a pipe layer PL, which includes or consists of conductive material in the back gate BG and configures a back gate transistor BTr. The word lines WL are in line along the z-axis and y-axis with an interval. Each word line WL is penetrated by semiconductor columns SP which are in line along the x-axis, and therefore shared by memory cell transistors MTr located along the x-axis. Memory space which consists of memory cell transistors MTr connected to the same word line WL configures one page. The insulating layer IN2 extends over the surface of a hole, in which the semiconductor pillar SP is buried, and includes a tunnel insulation film IN2a, a charge storage layer IN2b of insulating material, and an inter-electrode insulation film IN2c as shown in the magnified view. Each memory cell transistor MTr non-volatilely stores data determined in accordance with the number of carriers in the charge storage layer IN2b.

The select gate transistors SSTr and SDTr each include one semiconductor pillar SP and a gate insulating film IN4 over the surface of the semiconductor pillar SP, and they also include gate electrode SGS and SGD extending along the x-axis, respectively. Source/drain areas are formed in the semiconductor-pillars SP. Each gate electrode SGS is penetrated by semiconductor-pillars SP which are in line along the x-axis, and therefore shared by select gate transistors SSTr located along the x-axis. Each gate electrode SGD is penetrated by semiconductor-pillars SP which are in line along the x-axis, and therefore shared by select gate transistors SDTr located along the x-axis.

Each source line SL is connected to each select gate transistor SSTr of memory units located along the x-axis. The bit lines BL are in line along the x-axis. Each bit line BL is connected to each select gate transistor SDTr of memory units MU located along the y-axis via a plug CP1. Two adjacent memory units MU are symmetrical with respect to the z-axis, and shares one source line SL.

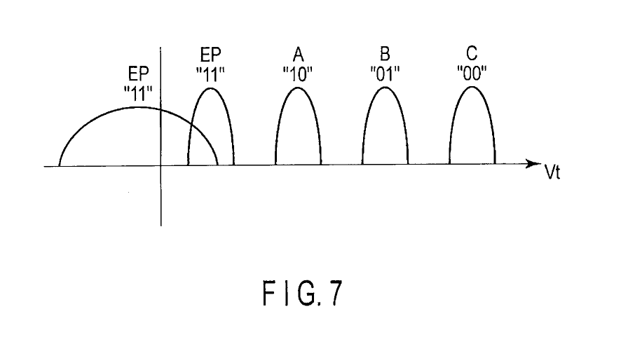

The semiconductor memory device shown in FIGS. 4 to 6 is a so-called BiCS-type flash memory (or, a BiCS memory). This results in the charge storage layer IN2b being shared by the memory cell transistors MTr unlike the plane memory as described above. This, in turn, may cause the following phenomena. The following description assumes a two-bits/cell case as an example for purpose of clarified description. Specifically, threshold voltage distribution of the memory cell transistors MTr can take any of one type of negative distribution (E) and four types of positive distribution (EP, A, B, and C). FIG. 7 shows a relationship between two-bit four-level data (data “11”, “10”, “01”, or “00”) stored by the memory cell transistors MTr, and threshold voltage distribution of the corresponding memory cell transistors MTr. Here, data “11” (E, EP) indicates an erased state, and data “10”, “01”, and “00” (A, B, C) indicates written states. The lower end of the threshold voltage distribution E has a negative value. The lower end the threshold voltage distribution EP and A, B, and C has a positive value. The threshold voltage distribution EP and A, B, and C is in line along the positive direction in the mentioned order with a margin.

In order to set a certain memory cell transistor MTr to the erased state, the holes are trapped in its charge storage film IN2b to move the current threshold voltage distribution EP and A, B, or C in the negative direction to the threshold voltage distribution E. However, when a certain memory cell transistor MTr has the threshold voltage distribution E and its adjacent memory cell transistor MTr a different threshold voltage distribution (e.g., A), electrical charges (i.e., electrons and holes) travel between the two memory cell transistors MTr over time, because the charge storage layer IN2b is contiguous over the memory cell transistors MTr1 to MTr8. This may cause loss of stored data and deteriorate data retention. As a countermeasure, memory cell transistors MT to be programmed are first given the threshold voltage distribution E, and then their respective charge storage layer IN2b have the electrons trapped to make the threshold voltage distribution EP. As a result, the erased memory cell transistors MTr have positive threshold voltage distribution. With such a difference from the plane memory, the memory according to the first embodiment cannot use the aforementioned coupling-reducing techniques adopted by the plane memory.

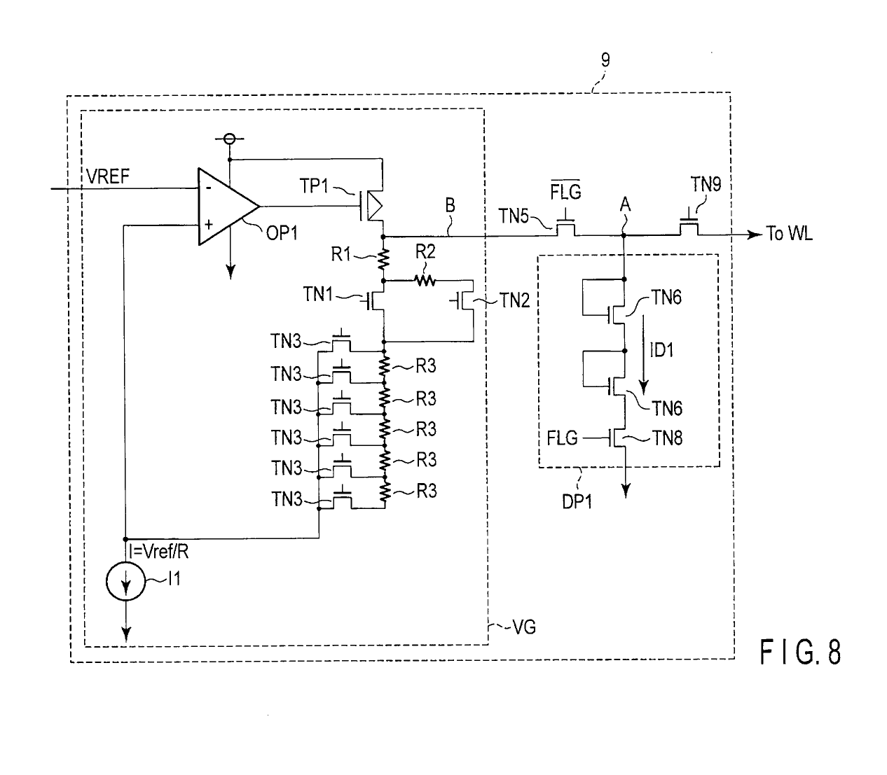

Referring to FIG. 8, the voltage generator 9 will now be described. FIG. 8 illustrates a circuit diagram of the voltage generator 9 according to the first embodiment, and a part of the voltage generator 9 for generating the isolation voltage VISO (, which may be referred to as a VISO generator hereinafter). The VISO generator generates the voltage VISO. As shown in FIG. 8, an inverting input of an operational amplifier OP1 receives a reference voltage VREF (e.g., 1.2V). The output of the operational amplifier OP1 is connected to the gate of a p-type metal oxide semiconductor field effect transistor (MOSFET) TP1. The transistor TP1 receives the supply voltage at one end, and is connected to one end of a resistor R1 at the other end. The other end of the resistor R1 is connected to one end of an n-type MOSFET TN1 and is also connected to the other end of the transistor TN1 via serially-connected resistor R2 and an n-type MOSFET TN2. The connection node between the transistors TN1 and TN2 is connected to one end of serially-connected resistors R3 (five resistors illustrated in the figure). The other end of the set of the serially-connected resistors R3 is connected to a current source I1 and a non-inverting input of the operational amplifier OP1. The serially-connected resistors R3 are also connected to n-type MOSFETs TN3 (of the number of the resistances R3 plus one). That is, each end of the set of the serially-connected resistors R3 is connected via one of transistors TN3 to the non-inverting input of the operational amplifier OP1, to which the connection node among the resistors R3 are also connected. Each gate of the transistor TN1, TN2, and TN3 receives from the controller 7 a signal which is based on the control signals. The operational amplifier OP1, transistors TP1, and TN1 to TN3, resistors R1 to R3, and current source I1 configure a voltage generator VG. Some of the transistors TN1 to TN3 are selected based on the signals received from the controller 7 to generate the desired voltage VISO or VCHPCH.

The connection node between the resistor R2 and transistor TN2 is connected to a discharge path DP1 via an n-type MOSFET TN5. The transistor TN5 receives the negative logic /FLG of a signal FLG (to be described later) at the gate electrode. The discharge path DP1 includes diode-connected n-type MOSFETs TN6 (the figure illustrates two pieces). The diode-connected transistors TN6 are serially connected, and one end of such serial structure is connected to the other end of the transistor TN5. The other end of the serial structure is grounded via an n-type MOSFET NT8. The transistor TN8 receives the signal FLG at the gate electrode. The signals FLG and /FLG are generated by the controller 7. The connection node A between the discharge path DP1 and transistor TN5 is connected to one end of an n-type MOSFET TN9. The other end of the transistor TN9 serves as an output of the voltage generator 9 and is electrically connected to a word line WL which will be charged to the isolation voltage VISO. The transistor TN9 is for controlling the voltage generator 9 to and from the word line controller 6, and receives a signal from the controller 7 at the gate electrode. The voltage generator 9 includes at least a portion for generating the voltage VPASS (referred to as a VPASS generator) and a portion for generating the program voltage VPGM (referred to as a VPGM generator), none of which is illustrated, as well as the VISO generator. The VISO generator, VPASS generator, and VPGM generator will be connected to specific word lines WL by control of the word line controller 6.

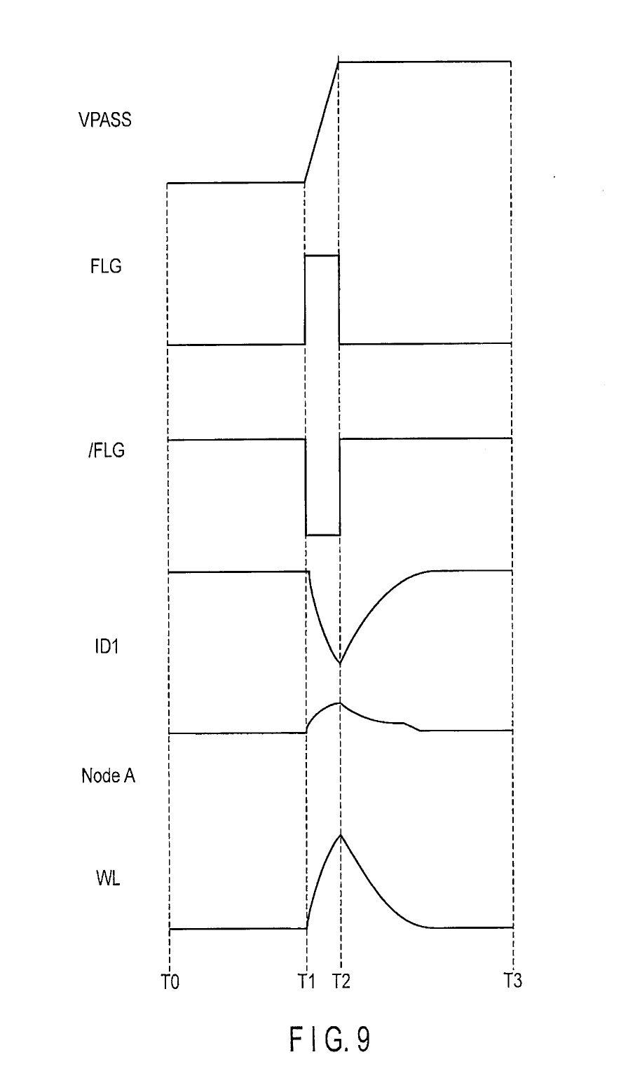

Referring to FIG. 9, operation of the voltage generator (or, the VISO generator) of FIG. 8 will now be described. FIG. 9 illustrates a timing chart for voltages of main components of the VISO generator of the FIG. 8 and associated components during data writing. For data writing, the program-voltages VPGM is applied to a selected word line WL by the VPGM generator. A word line WL adjacent the selected word line WL is driven to the voltage VPASS by the VPASS generator. A word line WL adjacent the word line WL which will be driven to the voltage VPASS is driven to the voltage VISO by the VISO generator of FIG. 8. The VISO generator first generates the channel precharge voltage VCHCHP applied to one or more specific word lines WL as described above during data program in order to set their channels to a specific voltage. The voltage VCHPCH is in turn applied to the specific word line(s) WL. With the start of data writing, the VISO generator is switched to generate the voltage VISO.

As shown in FIG. 9, the signal /FLG is asserted (or, made high), and the output node B of the voltage generator VG is connected to the word line WL which will be driven to the voltage VISO. The time T0 to T1 is for applying the voltage VCHPCH. The rising of the voltage VPASS takes from the time T1 to T2. Reducing the coupling from the word line WL which will be charged to the voltage VPASS is desired during the time T1 to T2 taken by the voltage VPASS to rise. To this end, the signal /FLG is negated (or, made low) during the time T1 to T2, and the output node B of the voltage generator VG is disconnected from the word line WL which will be charged to the voltage VISO. The potential of the illustrated word line WL, which will be charged to the voltage VISO, increases by the coupling from the adjacent word line WL which will be charged to the voltage VPASS. As a result, the potential of the node A also increases.

In parallel to disconnection between the output node B and the word line WL, the signal FLG is made asserted (or, made high) during the time T1 to T2. As a result, the discharge path DP1 is enabled, and therefore the potential of the word line WL which will be charged to the voltage VISO is pulled down to a potential of the earth VSS plus a total threshold voltages of all diode-connected transistors TN6. Therefore, a discharge current ID1 through the discharge path DP1 increases, and potentials of the node A and the word line WL which will be charged to the voltage VISO fall. The potential of the word line WL which will be charged to the voltage VISO promptly falls to a value near the prior voltage VPASS application as can be seen from FIG. 9.

At the time T2, the rising of the voltage VPASS is completed, and the signals FLG and /FLG are negated and asserted back, respectively. As a result, the word line WL which will be driven to the voltage VISO is connected to the output node B and charged to the voltage VISO until the time T3.

As described, in the semiconductor memory device according to the first embodiment, the voltage generator for driving the word line WL influenced by the coupling from the adjacent word line WL (or, the VISO generator) includes the transistor TN5 for being disconnected from such a word line WL and the discharge path DP1 for discharging. The VISO generator is disconnected from the word line WL of interest by the transistor TN5 and the word line WL of interest is discharged by the discharge path DP1 during the rise of the voltage on the adjacent word line WL. Therefore, the word line WL of interest can be pulled down to the earth and promptly brought back to the voltage near prior voltage VPASS application during the rise of the adjacent word line WL. This can realize a semiconductor memory device with accelerated operation.

### Second Embodiment

In the second embodiment, the voltage generator 9 (or, the VISO generator) has a different discharge path from the first embodiment.

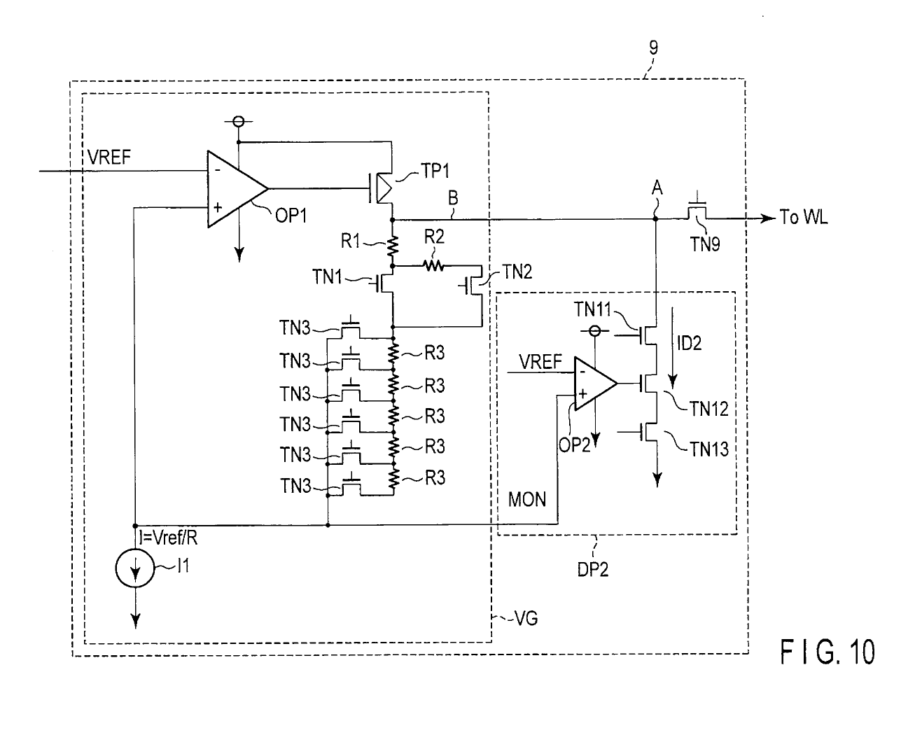

FIG. 10 illustrates a circuit diagram of the voltage generator 9 according to the second embodiment, and a portion of the voltage generators 9 for generating the voltage VISO. As shown in FIG. 10, the portion of the voltage generator 9 for the voltage VISO (or, the VISO generator) includes a discharge path DP2 instead of the discharge path DP1 of FIG. 8 and does not include the transistor T5. The configuration of the remaining portion of the voltage generator 9 and the whole semiconductor memory device is the same as the first embodiment. Particularly, the voltage generator 9 is also the VCHPCH generator.

The discharge path DP2 includes serially-connected n-type MOSFETs TN11, TN12, and TN13, and an operational amplifier OP2. The set of the serially-connected transistors TN11, TN12, and TN13 is connected between the node A and the ground VSS. The gate of the transistor TN11 receives a voltage sufficient to turn on the transistor TN11. The gate of the transistor TN12 is connected to an output of the operational amplifier OP2. The gate of the transistor TN13 receives from the controller 7 the same signal as the signal for enabling the operational amplifiers OP1 and OP2 (not shown). A non-inverting input of the operational amplifier OP2 receives a reference voltage VREF (e.g., 1.2V), and its inverting input is input to the inverting input of the operational amplifier OP1 as the signal MON.

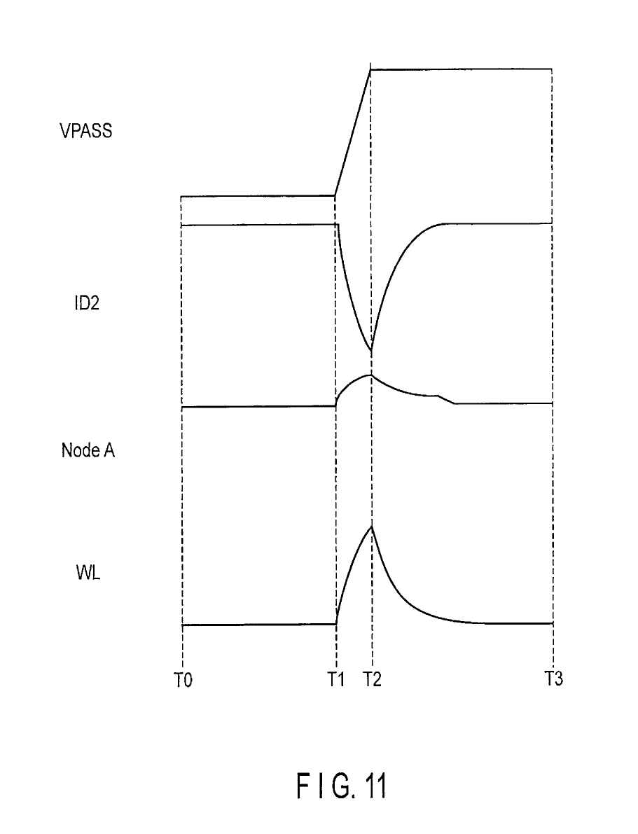

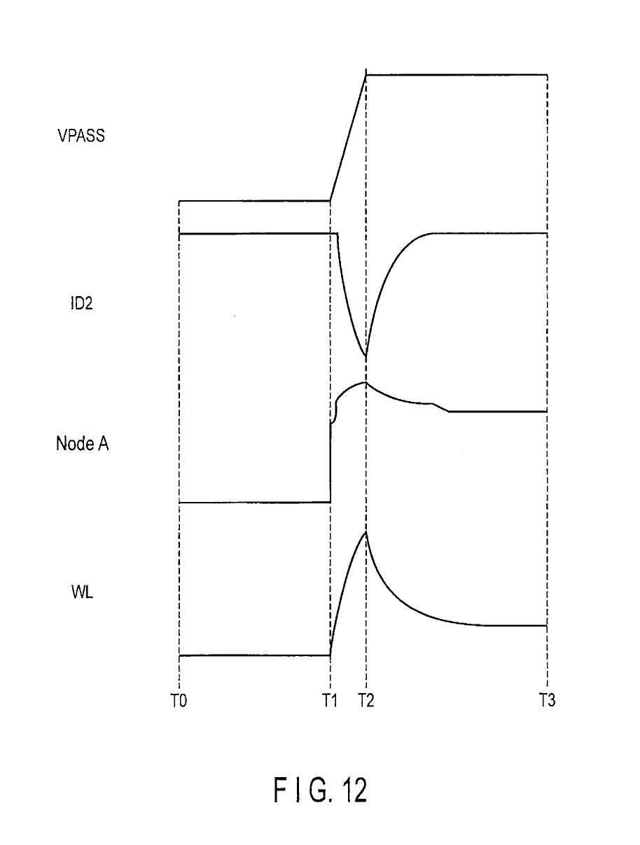

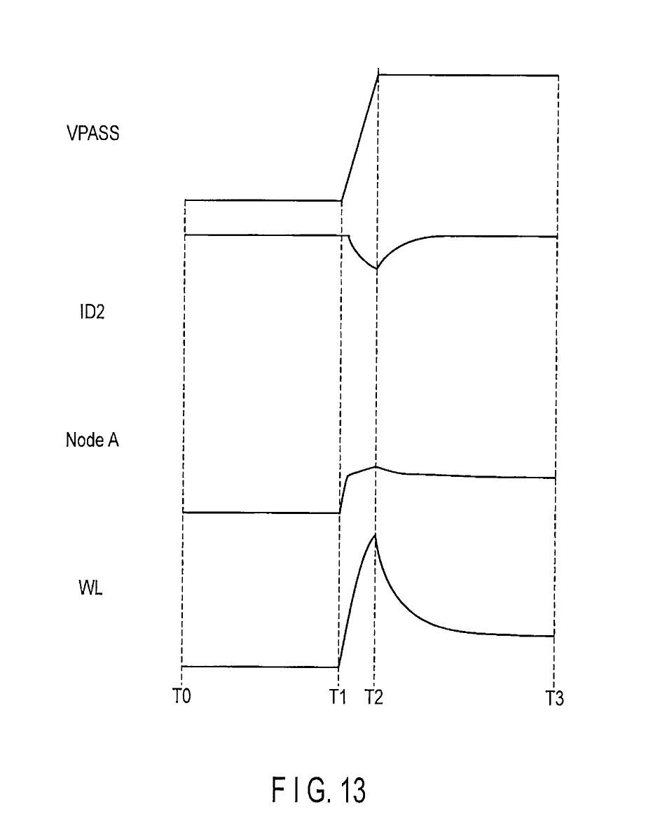

Referring to FIGS. 11 to 13, operation of the voltage generator (or, VISO generator) of FIG. 10 will now be described. FIGS. 11 to 13 illustrate timing charts for voltages of main components of the VISO generator of FIG. 10 and associated components. FIGS. 11 to 13 illustrate charts for different isolation voltages VISO. Specifically, the voltages for FIGS. 11 to 13 are 2, 3.75, and 4V, respectively. However, a specific value for the voltage VISO is determined by the combination of various details such as connection of many components of the semiconductor memory device, applied voltages, control, and timing. Therefore, the introduced values above are mere examples selected under specific conditions. As in the first embodiment, a selected word line WL, a word line WL adjacent the selected word line WL, and the second word line WL from the selected word line WL are driven to the voltage VPGM, VPASS, and VISO for data writing, respectively.

As shown in FIGS. 11 to 13, the rise of the voltage VPASS takes from the time T1 to T2. The time T0 to T1 is for applying the voltage VCHPCH. The potential of the illustrated word line WL, which will be charged to the voltage VISO, increases by the coupling from the adjacent word line WL which will be charged to the voltage VPASS. With the increase of the voltage VPASS, the potential of the node A also increases. When the voltage MON exceeds the voltage VREF as a result of the increase of the potential of the node A, the output of the operational amplifier OP2 is turned on, and the discharge path DP2 is enabled. As a result, a discharge current ID2 increases, and therefore the potential of the node A and the potential of the word line WL which will be charged to the voltage VISO decrease. The potential of the word line WL which will be charged to the voltage VISO promptly falls to a value near the prior voltage VPASS application before the time T3 as can be seen from FIGS. 11 to 13. When the voltage MON falls below the voltage VREF, the output of the operational amplifier OP2 is turned off to disable the discharge path DP2, which decreases the discharge current ID2. Thus, since the voltage of the node A is detected to enable and disable the discharge path DP2 autonomously, control of the discharge path DP2 based on timing is unnecessary unlike in the first embodiment. For regards other than those described above, the description for the first embodiment is applied.

As described, in the semiconductor memory device according to the second embodiment, the voltage generator for driving the word line WL influenced by the coupling from the adjacent word line WL (or, the VISO generator) includes the discharge path DP2. When the word line WL of interest exceeds a specific voltage, the discharge path DP2 pulls the word line WL of interest to the earth. With this, the voltage of the word line WL which will be charged to the voltage VISO and is connected to the output of the VISO generator can be promptly brought back to the voltage near the prior voltage VPASS application. This in turn can realize a semiconductor memory device with accelerated operation. Also according to the second embodiment, since the discharge path DP2 is autonomously enabled and disabled based on the voltage of a node, control of the VISO generator is easy. Note that since a specific value of the voltage VISO is determined based on various details as described above, it is not that the above-mentioned advantages can only be obtained with values introduced above.

### Third Embodiment

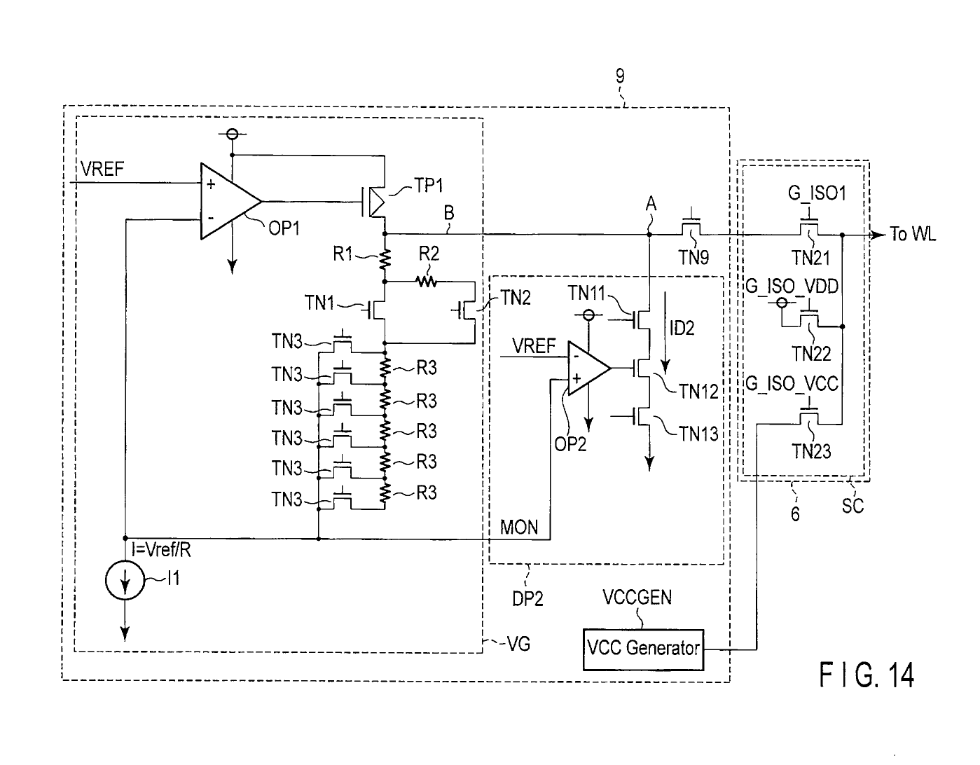

The third embodiment includes a component additional to the second embodiment. FIG. 14 illustrates a circuit diagram of the voltage generator 9 and a part of the word line controller 6 according to the third embodiment. The voltage generator 9 illustrates a portion for generating the voltage VISO. As shown in FIG. 14, the portion for the voltage VISO of the voltage generator 9 (or, the VISO generator) is the same as FIG. 10. The word line controller 6 includes an n-type MOSFET TN21, TN22, and TN23. The transistor TN21 is connected between the output of the VISO generator (or, the other end of the transistor TN9) and the word line WL which will be charged to the isolation voltage VISO. The gate of the transistor TN21 receives a signal G_ISO1 from the controller 7. The signal G_ISO1 is for selecting whether the voltage generator 9 is to be connected to the word line WL.

One end of each transistor TN22 and TN23 is connected to where the transistor TN21 is connected to the word line WL. The other end of the transistor TN22 receives the supply voltage VDD. The other end of the transistor TN23 receives the voltage VCC from the voltage generator 9. The voltage VCC is higher than the voltage VDD. The gates of the transistors TN22 and TN23 receive signals G_ISO_VDD and G_ISO_VCC from the controller 7, respectively. The transistors TN21 to TN23 configure a circuit for disconnecting the word line WL from the VISO generator and coupling it to the voltage VDD or VCC (referred to as a connection circuit SC). The configuration of the remaining portion of the voltage generator 9 and the whole semiconductor memory device is the same as the first embodiment.

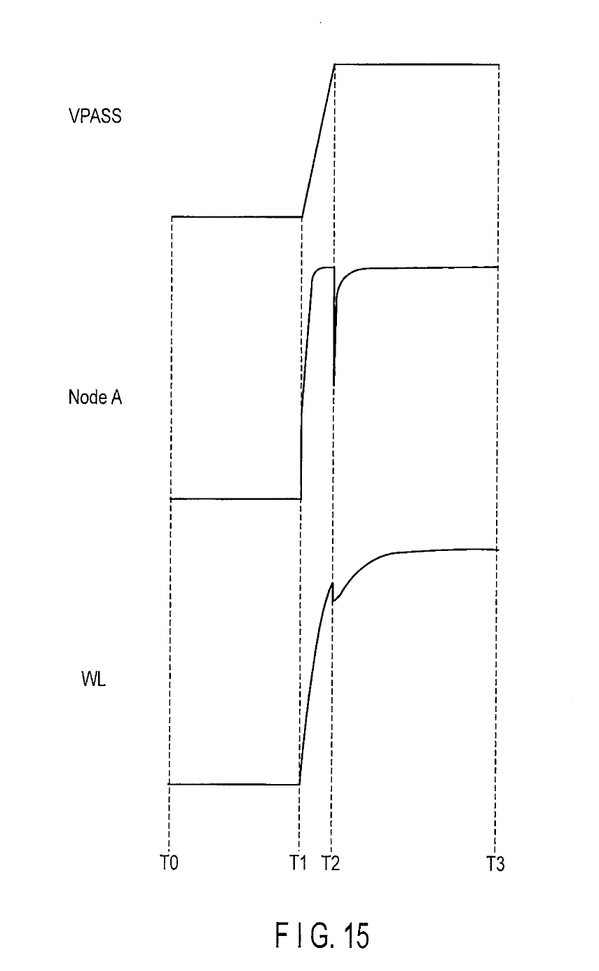

Referring to FIG. 15, operation of the voltage generator of FIG. 14 (or, the VISO generator) and the word line controller will be described. FIG. 15 illustrate a timing chart for a voltage of a main component of the VISO generator of the FIG. 10 and associated components during data writing. For data writing, the selected word line WL is driven to the program voltage VPGM by the VPGM generator. The word line WL adjacent the selected word line WL is driven to the voltage VPASS by the VPASS generator. The word line WL adjacent the word line WL which will be driven to the voltage VPASS is driven to the voltage VISO by the VISO generator of FIG. 8. The voltage VCHPCH is applied to one or more specific word lines WL during the time T0 to T1 as in FIGS. 11 to 13. At the time T1, the VISO generator is connected to the word line WL as in the second embodiment.

As shown in FIG. 15, the rise of the voltage VPASS takes from the time T1 to T2. During the time T1 to T2, the signal G_ISO1 is negated (or, made low), which disconnects the VISO generator from the word line WL which will be charged to the voltage VISO. The signal G_ISO_VDD is also asserted (or, made high) during the time T1 to T2. As a result, the transistor TN22 is turned on, the word line WL which will be charged to the voltage VISO is fixed to the voltage VDD, and the voltage fluctuation by the coupling from the adjacent word line WL is eased. The potential of the word line WL which will be charged to the voltage VISO rises toward the voltage VDD. Alternatively, the signal G_ISO_VCC is negated (or, made high) during the time T1 to T2 to turn on the transistor TN23, which triggers the rise of the potential of the word line WL which will be charged to the voltage VISO toward the voltage VCC. In contrast, the VISO generator starts operation prior to the time T1, and produces the voltage VISO at the node A.

Once the rise of the voltage VPASS finishes at the time T2, the transistor TN21 is turned on and the previously-turned-on transistor TN22 or TN23 is turned off. The following behavior of the voltages is different based on whether the voltage VISO is lower or higher than the voltage VDD (or VCC). For a case of the voltage VISO higher than the voltage VDD (or VCC), the word line WL which will be charged to the voltage VISO keeps rising toward the voltage VISO resulting from the transistor TN21 turned on. In contrast, for a case of the voltage VISO lower than the voltage VDD (or VCC), the word line WL which will be charged to the voltage VISO is pulled down toward the earth VSS by the discharge path DP2 to the voltage VISO.

As described, in the semiconductor memory device according to the third embodiment, the voltage generator 9 has the same configuration as the second embodiment and the word line controller 7 includes the connection circuit SC for fixing the word line WL to a specific voltage. The connection circuit SC fixes the word line WL to a specific potential during the rise of the voltage VPASS. For this reason, the potential of the word line WL which will be charged to the voltage VISO can be fixed to the potential of the external power applied directly from pads, which can reduce the coupling from the adjacent word line WL which will be charged to the voltage VPASS. Furthermore, after the rise of the voltage VPASS, the word line WL which will be charged to the voltage VISO is discharged by the discharge path to be controlled to the voltage VISO based. Thus, the word line WL can be protected from the influence of the coupling and controlled to a desired potential. This can realize a semiconductor memory device with accelerated operation.

### Fourth Embodiment

The fourth embodiment relates to speed of rise of the voltage VPASS.

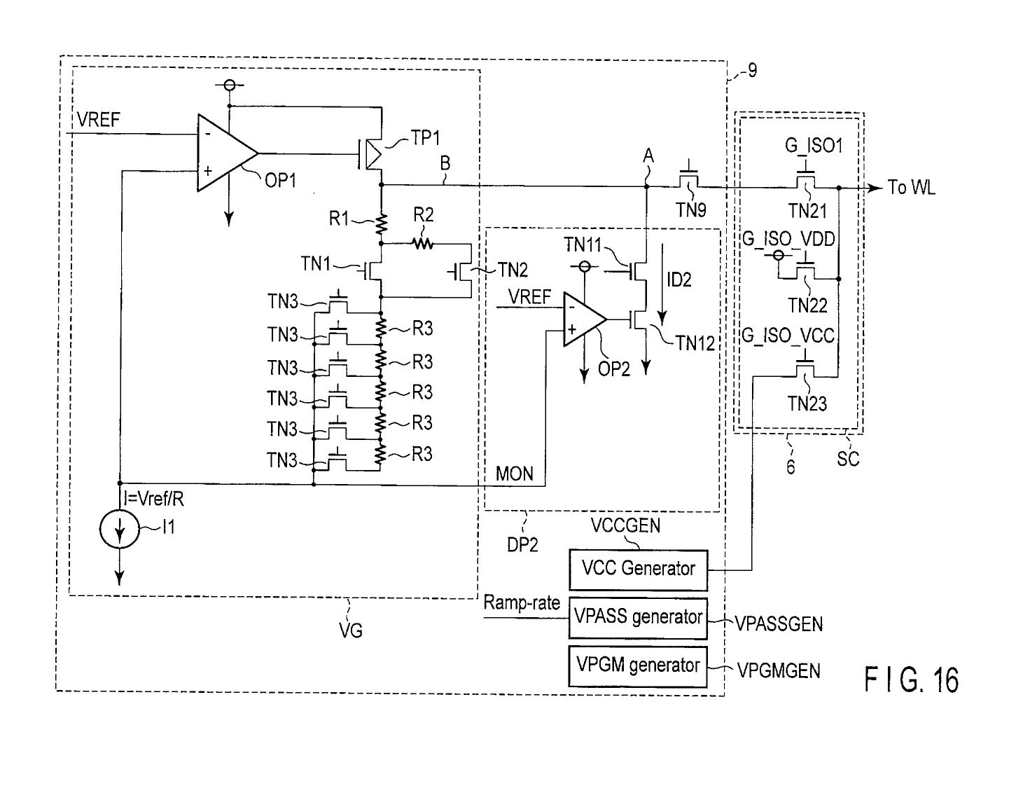

FIG. 16 illustrates a circuit diagram of the voltage generator 9 and a part of word line controller 6 according to the fourth embodiment. As shown in FIG. 16, the portion for generating the voltage VISO (or, the VISO generator) has the same configuration as the third embodiment. The portion of the word line controller 6 connected to the VISO generator also has the same configuration as the third embodiment. In contrast, the portion of the voltage generator 9 which generates the voltage VPASS (or, the VPASS generator VPASSGEN) receives a signal Ramp_rate from the controller 7. The signal Ramp_rate controls speed of rise of the voltage VPASS. The voltage VPASS rises at a determined speed based on the signal Ramp_rate. The configuration of the remaining portion of the voltage generator 9 and the whole semiconductor memory device is the same as the first embodiment.

A slower rise of the voltage VPASS can ease the undesired voltage rise due to the coupling to the word line WL which will be charged to the voltage VISO and adjoins the word line WL which will be charged to the voltage VPASS. However, a slower rise of the voltage VPASS also decelerates the operation of the semiconductor memory device. Furthermore, since a higher voltage of the node A facilitates discharging by the discharge path DP2, it also takes longer for the word line WL to fall to a target voltage (i.e., voltage VISO). Therefore, the rise speed of the voltage VPASS is determined with a required operation speed of the semiconductor memory device considered. The operation other than that described above is the same as the third embodiment.

As described, in the semiconductor memory device according to the fourth embodiment, the voltage generator 9 has the same configuration as the second embodiment and the word line controller includes the connection circuit for fixing the word line to a specific voltage as in the third embodiment. Therefore, the same advantage as the third embodiment can be obtained. Furthermore, the speed of rise of the voltage VPASS can be controlled in the semiconductor memory device according to the fourth embodiment. For this reason, the undesired voltage rise of the word line WL which will be charged to voltage VISO due to the coupling can be eased through suitable control of the rise speed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
memory cells storing data based on respective threshold voltages, having a positive threshold voltage in a data erased state, and comprising respective control electrodes;
word lines selectively electrically connected to the control electrodes of the memory cells, and charged to a potential before writing data to the memory cells;
a voltage generator outputting a voltage at an output and includes a first path which discharges the output; and
a connection circuit selectively electrically connected to the output of the voltage generator and a first word line, and selectively electrically connecting the first word line to a first node which supplies a potential.

2. The device of claim 1, wherein
the connection circuit electrically disconnects the first word line from the output of the voltage generator and electrically connects the first word line to the first node during rise of a voltage applied to a second word line adjacent the first word line.

3. The device of claim 2, wherein
the first path is turned on and off based on a magnitude of the output of the voltage generator.

4. The device of claim 3, wherein
the first path comprises:
at least one transistor electrically connected between the output of the voltage generator and the ground; and
an operational amplifier configured to turn on one of the at least one transistor based on comparison between a voltage based on the output of the voltage generator and a reference voltage.

5. The device of claim 2, wherein
the second word line adjoins a third word line which receives a third voltage supplied to the control electrode of one memory cell into which data is written.

6. The device of claim 1, wherein
the voltage generator generates the second voltage with varying rise speed.

7. A semiconductor memory device comprising:
memory cells storing data based on respective threshold voltages, having a positive threshold voltage in a data erased state, and comprising respective control electrodes;
word lines selectively electrically connected to the control electrodes of the memory cells, and charged to a potential before writing data to the memory cells;
a voltage generator outputting a voltage at an output and includes a first path which discharges the output; and
a connection circuit electrically coupling the output of the voltage generator and a first word line, and electrically disconnecting the output of the voltage generator and the first word line during rise of a voltage applied to a second word line adjacent the first word line, wherein
the first path is enabled during the rise of the voltage applied to the second word line.

8. The device of claim 7, wherein
the second word line adjoins a third word line which receives a third voltage supplied to the control electrode of one memory cell into which data is written.

9. A semiconductor memory device comprising:
memory cells storing data based on respective threshold voltages, having a positive threshold voltage in a data erased state, and comprising respective control electrodes;
word lines selectively electrically connected to the control electrodes of the memory cells, and charged to a potential before writing data to the memory cells;
a voltage generator outputting a voltage at an output and including a first path which discharges the output and comprises at least one transistor and an operational amplifier, the at least one transistor electrically serially-connected between the output of the voltage generator and the ground, the operational amplifier turning on the at least one transistor based on comparison between a reference voltage and a voltage which is based on the output of the voltage generator.

10. The device of claim 9, further comprising a connection circuit selectively electrically connected to the output of the voltage generator and a first word line, and selectively electrically connecting the first word line to a first node which supplies a potential

11. The device of claim 10, wherein
the second word line adjoins a third word line which receives a third voltage supplied to the control electrode of one memory cell into which data is written.
